(19) United States
(12) Patent Application Publication
(10) Pub. No.: US 2010/0209855 A1
(43) Pub. Date: Aug. 19, 2010

(54) METHOD AND APPARATUS FOR MANUFACTURING SEMICONDUCTOR DEVICE AND RESIST MATERIAL

(76) Inventor: Toshihiko Tanaka, Tokyo (JP)

Correspondence Address: MCDERMOTT WILL & EMERY LLP, 600 13TH STREET, N.W., WASHINGTON, DC, 20005-3096, US

(21) Appl. No.: 12/678,977

(22) PCT Filed: Sep. 16, 2008
(86) PCT No.: PCT/JP2008/066646

§ 371 Date: Mar. 18, 2010

(30) Foreign Application Priority Data
Sep. 25, 2007 (JP) 2007-247125

(51) Int. Cl. G03F 7/20; G03B 27/42

(52) U.S. Cl. 430/319; 355/53

(57) ABSTRACT

Disclosed is a method for manufacturing semiconductor devices including steps of: forming on a wafer W a resist film 102 of a developer-repellent material, which has a contact angle of, e.g., 65 degrees or more with a developer; exposing the resist film 102 with a desired pattern of light; oxidizing a surface layer of the resist film 102 to render the surface layer 104 hydrophilic; and developing the resist film 102 using the developer to form a resist pattern 105, whereby solving both of collapsing of the pattern due to micro-swelling and dimensional variations of the pattern due to nonuniformity of development to improve yielding of product.

### TECHNICAL FIELD

The present invention relates to a lithographic technique used for manufacturing a semiconductor device, more particularly to a technique for manufacturing a fine resist pattern having high accuracy of dimension with a high production yield.

### BACKGROUND

In a manufacturing process of a semiconductor device such as a semiconductor integrated circuit, a lithography technique is employed for a method for transferring a fine pattern onto a substrate. A projection aligner is very often used in the lithography, wherein a resist formed on a substrate is irradiated with exposure light transmitted through or reflected from a photo mask mounted in the projection aligner to transfer patterns. In recent years, it is increasingly demanded that the device be more densely integrated and an operation speed be increased, and researches for pattern miniaturization are under way to meet these demands.

For example, a projected image can have an improved resolution by using exposure light having a shorter wavelength, and a keen interest is recently placed on an exposure technique with EUV (Extreme Ultra Violet) light having a wavelength of 13.5 nm, which is shorter than that of conventional ultraviolet light by at least an order of magnitude.

### [PATENT DOCUMENT 1] JP-2002-16151, A

### [PATENT DOCUMENT 2] JP-2003-303752, A

### DISCLOSURE OF THE INVENTION

### Problem to be Solved by the Invention

The resolution of a projected image has been tremendously improved by upgrading the projection aligner. However, a practical problem occurred that a resist pattern 201 formed on a wafer W collapsed during formation thereof, as shown in FIG. 2, resulting in deterioration of a production yield.

A main cause of the resist pattern collapse is a capillary force of a rinse agent generated when the rinse agent is drying out after the resist is developed. Another significant cause of the pattern collapse is a phenomenon that is generally called micros-welling, wherein when a developer and the rinse agent are present around the resist, these fluids penetrate into the resist to swell it, thereby making one resist pattern to come in contact with another resist pattern adjacent thereto.

The amount of the fluid penetrating into the resist is rather small, however, it is easier for the fluid to penetrate into the pattern with the dimension of the pattern to be formed being smaller. Therefore, it is necessary to work out effective measures to prevent the occurrence of such a micro-swelling in case of using EUV exposure light.

The micro-swelling can be alleviated by enhancing the water repellancy of the resist to make it harder for the fluid, such as developer and rinse agent, to penetrate into the resist. This approach, however, brings about another problem that the wettability of the developer is also degraded, which undermines uniformity of dimensions within a wafer. As a result, the production yield is deteriorated.

In order to reduce manufacturing costs, wafers manufactured these days are designed to have gradually larger diameters, e.g., 200 mm, 300 mm and then 450 mm. Along with the recent trend, one of important issues is to further improve uniformity of development within a wafer.

An object of the present invention is to provide a method and an apparatus for manufacturing a semiconductor device and a resist material, which can solve the above-mentioned conventional problems including both of the pattern collapse due to micros-welling and the variability of pattern dimensions due to the nonuniformity of development, thereby improving a production yield.

### Means for Solving the Problem

According to an embodiment of the present invention, a developer-repellent resist film is formed, and then the resist film is exposed with a desired pattern of light, and then a surface layer of the resist film is oxidized to be thereby hydrophilized. Thereafter, the resulting resist film is developed using a developer so that a resist pattern is formed.

According to another embodiment of the present invention, a developer-repellent resist film is formed, and then a thin film having solubility in an alkali aqueous solution is formed on the resist film, and then the resist film is exposed with a desired pattern of light. Thereafter, the resulting resist film is developed using a developer so that a resist pattern is formed.

According to still another embodiment of the present invention, an apparatus for manufacturing a semiconductor device, includes an exposure unit for performing an exposure with a desired pattern of light in vacuum, a resist modifying unit for modifying a surface layer of resist film at a reduced pressure, and a transport mechanism for transporting a specimen between the both units without undergoing the atmosphere.

According to yet another embodiment of the present invention, a resist material has a substantially rectangular cross section, and a contact angle of an upper surface of the resist material with a developer is smaller than a contact angle of a side surface of the resist material.

### EFFECT OF THE INVENTION

According to the above embodiments, even a fine pattern can be successfully prevented from collapsing as observed in conventional patterns. Further, uniformity of development and uniformity of dimension within a substrate can be surely achieved. As a result, a production yield of a semiconductor device, such as a semiconductor integrated circuit, can be improved.

### BRIEF DESCRIPTION OF THE DRAWINGS

FIGS. 1A to 1D are sectional views showing an example of a resist treatment.

FIG. 2 is a sectional view showing a collapse of a resist pattern.

FIG. 3 is a structural view showing an example of a lithography apparatus to which the present invention can be applied.

FIG. 4 is a structural view showing an example of a modifying unit provided in resist interface modifying equipment.

FIG. 5 is a detailed view of a resist pattern.

FIGS. 6A to 6F are sectional views showing an example of a process for manufacturing a semiconductor device.

FIGS. 7A to 7D are sectional views showing another example of the resist treatment.

### EXPLANATORY NOTE

3s substrate, 6n n-type well, 6p p-type well, 8 gate insulation film, 9 gate electrode, 102, 136 resist film, 102a resist side wall, 103 exposure light, 104 surface layer, 105, 107 resist pattern, 106 thin film, 121 resist treatment equipment, 122 exposure equipment, 122a exposure unit, 123 resist interface modifying equipment, 124, 125, 126 transport mechanism, 130 treatment chamber, 131 wafer stage, 132 lamp, W wafer.

### BEST EMBODIMENT FOR CARRYING OUT THE INVENTION

Hereinafter, preferred embodiments of the present invention will be described with reference to the drawings.

In the drawings, any components identical or corresponding to each other are denoted with the same numerals, so that lengthy description may be omitted.

### Embodiment 1

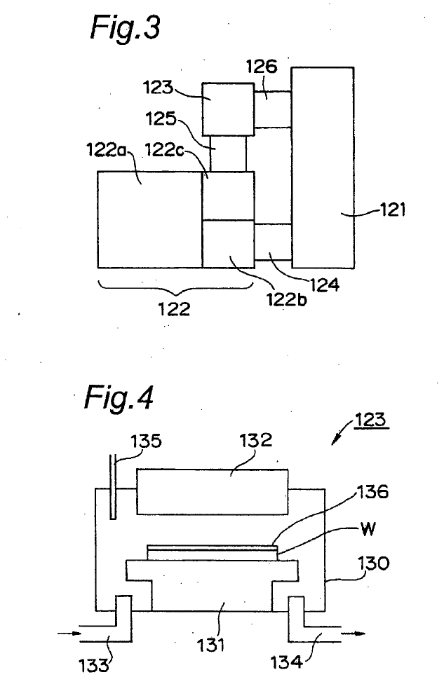

FIG. 3 is a structural view showing an example of a lithography apparatus to which the present invention can be applied. The lithography apparatus includes resist treatment equipment 121, exposure equipment 122, resist interface modifying equipment 123, transport mechanisms 124, 125 and 126 for coupling the respective equipments.

The resist treatment equipment 121 includes functions of, for example, applying a resist onto a wafer, performing a thermal treatment to the applied resist, and developing an exposed resist.

The exposure equipment 122 includes an exposure unit 122a, a load lock loader unit 122b, and an unloader unit 122c. The exposure unit 122a performs a scan exposure in vacuum to the wafer onto which the resist has been applied.

The load lock loader unit 122b receives in the atmosphere the wafer conveyed via the transport mechanism 124 from the resist treatment equipment 121, and then evacuates air therefrom to be vacuum, and then transfers the wafer in vacuum to the exposure unit 122a. The unloader unit 122c receives in vacuum the wafer which has been exposed in the exposure unit 122a, and then transfers the wafer to the resist interface modifying equipment 123 via the transport mechanism 125 in vacuum.

FIG. 4 is a structural view showing an example of a modifying unit provided in the resist interface modifying equipment 123. The modifying unit includes a treatment chamber 130, a wafer stage 131, a lamp 132, a gas supply tube 133, an exhaust pipe 134, and a measuring instrument 135 for measuring a degree of vacuum and an oxygen partial pressure. A wafer W with a resist film 136 formed thereon is placed on a wafer stage 131. The resist interface modifying equipment 123 includes a wafer transport mechanism and a carry-in/carry-out gate (shutter) in addition to the components described above.

An operation of the modifying unit will be described below. The treatment chamber 130 is supplied with an oxygen-containing treatment gas through the gas supply tube 133. The treatment gas may be a pure oxygen gas, or may be mixed with an inert gas, such as nitrogen or argon, as buffer gas to facilitate pressure control. The gas existing in the treatment chamber 130 is discharged by a vacuum pump (not shown) through the exhaust pipe 134, and the inside of the treatment chamber 130 is maintained in a depressurized state that is nearly vacuum.

The lamp 132 for generating vacuum ultraviolet light is provided at the top of the treatment chamber 132 so as to face the resist film 136. The lamp 132 preferably generates DUV (Deep Ultra Violet) light, particularly light having wavelengths shorter than 172 nm, so that only an extreme surface layer of the resist film 136 can be chemically altered.

For example, an Xe₂ excimer lamp having a peak wavelength of 172 nm, a Kr₂ excimer lamp having a peak wavelength of 146 nm, and an Ar₂ excimer lamp having a peak length of 126 nm can be used in view of energy efficiency. Among these lamps, light absorption in the resist is increased as the wavelengths are shorter. Therefore, the chemical reactions are localized only on a surface layer of the resist without extending any further. This can favorably inhibit an exposure to the resist bulk itself, thereby avoiding any impact on its transfer characteristics. However, for example, EUV light (wavelength of about 13 nm) and the like having an extremely short wavelength is not preferable because it adversely increases a penetration depth in the resist. Therefore, the Ar₂ excimer lamp is preferable as the lamp 132 provided in the modifying unit.

The modified surface layer of the resist preferably has a thickness equal to or less than 5 nm, and more preferably has a thickness equal to or less than 1 nm to avoid any impact on a resist pattern resolution.

Light irradiation from the lamp 132 can activate the surface layer of the resist film 136, and further activate oxygen existing in the treatment chamber 130 so that active oxygen and ozone are generated. The active oxygen and ozone, particularly the active oxygen, efficiently oxidizes the surface layer of the resist film 136 to modify the surface layer to be hydrophilic. The surface layer is more efficiently oxidized when irradiated with the vacuum ultraviolet light, thereby reducing the amount of time required for hydrophilizing the surface layer of the resist film 136.

At this time, it is necessary to depressurize the treatment chamber 130 so as to have a pressure of 10⁻² to 10⁻⁴ Torr. Otherwise, the thickness of the modified surface layer is unfavorably increased, which may be detrimental to a resolution pattern shape and resist resolving power. Further, the oxygen partial pressure of the treatment chamber 130 is preferably at least 20% in order to efficiently generate the active oxygen and ozone.

A heater for applying heat may be provided inside the wafer stage 131. When the wafer W and the resist film 136 are heated by energization of the heater as well as irradiation of light from the lamp 132, the surface layer of the resist film 136 is more efficiently activated, thereby further reducing the hydrophilizing time.

In the structure described above, there is described an example where both of the resist film 136 and the oxygen in the treatment chamber 130 are irradiated with the lamp light. However, the lamp light may be used only to generate the active oxygen and ozone without irradiating the resist film 136. For example, the lamp 132 may be provided at an intermediate of the gas supply tube 133, so that the active oxygen and ozone generated by the light irradiation may be introduced into the treatment chamber 130. Alternatively, the lamp 132 may be provided at an intermediate position in a route starting from the gas supply tube 133 and ending at an upper space of the resist film 136.

In accordance with the above structure, the hydrophilization of the resist film 136 may be slightly less efficient, while irradiation of the resist film 136 with the lamp light can be avoided at the same time. As a result, exposure to the resist bulk itself can be inhibited, and transfer characteristics thereof are free of any adverse impact. Further, since a possible impact on the resist can be disregarded in the selection of the wavelength of the lamp light, any lamp emitting light having a wavelength longer than 172 nm or shorter than 126 nm, which is capable of generating the active oxygen and ozone, can be used.

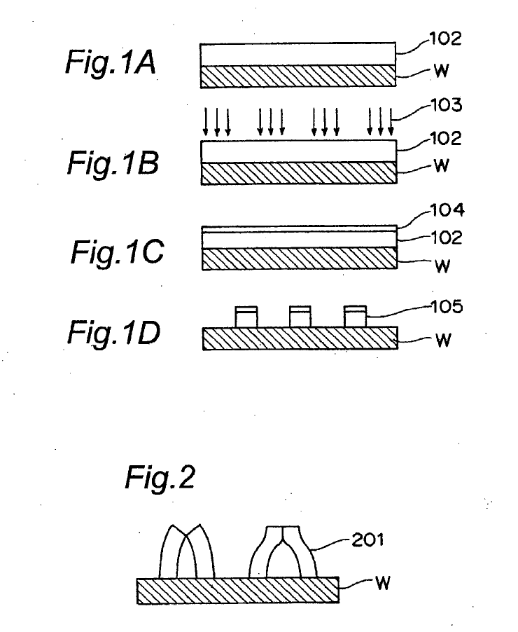

Next, a resist treatment process according to the present invention will be described with reference to FIGS. 1A to 1D. First, a resist is applied onto the wafer W and then thermally treated in a conventional manner so that a resist film 102 is formed as shown in FIG. 1A. In the case of optical lithography, an anti-reflective film, such as BARC (Bottom Anti-Reflective Coating), is formed prior to application of the resist. On the other hand, the anti-reflective film is not necessary in the case of EUV lithography.

In this case, a developer-repellent resist material is used for the resist. An aqueous solution including TMAH (tetramethyl ammonium hydroxide) of 2.38 wt % is used as a developer. The developer may include an additive agent such as a surface active agent, and the concentration of the TMAH included is not necessarily 2.38 wt %. The present invention brings about a surface oxidation effect described below by using a water-soluble developer.

The developer-repellency of the resist can be defined by a contact angle with the developer dropped on a surface of the resist film. It has become apparent from evaluations of various resist materials that any material having a contact angle of at least 65 degrees can effectively prevent the resist pattern from collapsing. Therefore, such a resist material having a contact angle of at least 65 degrees with the developer is preferably used for the resist film 102 shown in FIG. 1A.

It is necessary to measure the contact angle in a short period of time after the developer is dropped, because a development process advances as the resist and the developer are progressively blending in with each other over time. In this case, the contact angle is measured within 3 seconds after the developer is dropped. The measurement is preferably completed within 10 seconds at the latest.

Further, in a case where an excess amount of the developer is dropped, the contact angle which is controlled by an interfacial energy is subject to its own weight and thereby involves an error of measurement. Thus, the measurement becomes less accurate. In this case, 20 nl (nanoliters) was dropped for the measurement. The amount of the developer to be dropped is preferably 100 nl at most or below.

It is desirable to measure the contact angle using the developer to be actually used, however, pure water may be used instead when it is necessary to complete the measurement in a short period of time. In the case of pure water, which does not promote development of the resist, the measurement time after dropping can be extended by about 30 seconds. In a case where the contact angle obtained by the measurement using the developer is 65 degrees, it is equivalent to the contact angle of 72 degrees for pure water. Therefore, the resist film 102 shown in FIG. 1A is preferably made of a resist material in which the contact angle with pure water is at least 72 degrees.

More preferably, a resist material having the contact angle of at least 85 degrees with pure water (i.e., contact angle of at least 74 degrees with the developer) is used. Accordingly, when an interface of the rinse agent appears between the resist patterns, a Laplace force is also drastically reduced. As a result, the resist pattern collapse can be more effectively prevented.

A process as shown in FIG. 1A is carried out inside the resist treatment equipment 121 as shown in FIG. 3. Thereafter, the wafer W is transported via the transport mechanism 124 and the load lock loader unit 122b into the exposure unit 122a.

Next, an exposure process is performed to the resist film 102. As shown in FIG. 1B, the resist film 102 is irradiated with exposure light 103, which is projected by a projection optical system with a mask pattern having desired pattern. In the case of using EUV light having a wavelength of 13.5 nm for the exposure light 103, the exposure is performed in vacuum. After the exposure, the wafer W is transported into the resist interface modifying equipment 123 via the unloader unit 122c and the transport mechanism 125 as shown in FIG. 3. At this time, the wafer W can be transferred from the exposure process to the modifying process without undergoing the atmosphere. Therefore, a high production efficiency can be maintained, and adhesion of particles can be prevented as well.

Next, a surface modifying process is applied to the exposed resist film 102. The modifying process is carried out in the modifying unit of the resist interface modifying equipment 123 as shown in FIG. 4. As described above, the surface layer 104 of the resist film 102 is oxidized, as shown in FIG. 1C, by the active oxygen and ozone existing in the treatment chamber 130 and thereby hydrophilized. At this time, the contact angle with the developer on the surface layer 104 is 10 degrees or below. The contact angle with the developer is preferably smaller, but a stabler effect can be obtained with a contact angle of 20 degrees or below.

Next, the resist interface modifying equipment 123 is released into the atmosphere, and the exposed resist film 102 is thermally treated. Then, the developing process is carried out using the developer as described above, so that a resist pattern 105 as shown in FIG. 1D is obtained.

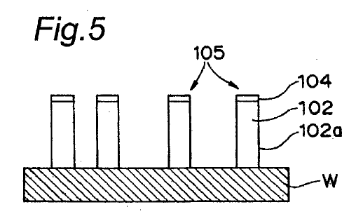

FIG. 5 is a detailed view of the resist pattern 105. The resist film 102 is made of a developer-repellent resist material, which makes it difficult for the developer to penetrate into a side wall 102a of the resist. On the other hand, the surface layer 104 of the resist film 102, whose contact angle with the developer is reduced using the modifying process, now obtains such a property that is more familiar with the developer. Therefore, higher uniformity of development and uniformity of dimension within the wafer surface are reliably retained, and micro-swelling on the resist side wall 102a can be prevented as well. As a result, the resist pattern can be reliably prevented from collapsing as shown in FIG. 2.

Herein, the active oxygen process alone or the combination of the active oxygen process and the vacuum ultraviolet light irradiation has been described as an example of the resist surface modifying process. In place of or in addition to these processes, plasma oxidation may be employed. The plasma oxidation enables only the extreme surface layer of the resist film to be oxidized by generating plasma under the oxygen partial pressure. In the plasma oxidation, conditions for generating plasma including, for example, a bias voltage, are adjusted so that the plasma does not exert an action inside the resist not to impact the resist resolution such that only the extreme surface layer of the resist film is oxidized.

The present embodiment has been described referring to the case of the EUV lithography. However, the present invention is also applicable to EB (electronic beam) lithography for similarly performing an exposure in vacuum, wherein the advantages, such as prevention of the resist pattern from collapsing, remarkable uniformity of dimension, prevention of pollution caused by particles, and reduction of the transport time from the exposure to resist treatment, can be utilized.

In the present embodiment, there is described an example where the processes were carried out in a sequence of resist application→exposure→resist surface modifying process→development. However, the processes can be also carried out in another sequence of resist application→resist surface modifying process→exposure→development.

As described above, the present embodiment can successfully prevent a pattern from collapsing as seen before even if it has a very fine dimension, thereby reliably retaining higher uniformity of development and uniformity of dimension within the wafer surface. As a result, a production yield in a semiconductor device, such as a semiconductor integrated circuit, can be improved.

### Embodiment 2

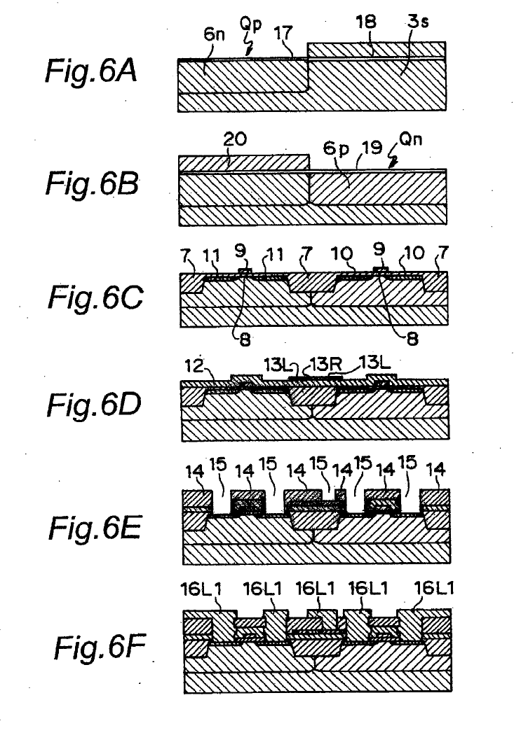

FIGS. 6A to 6F are cross-sectional views for explaining an example of a method for manufacturing a semiconductor device. Illustrated here is a case of manufacturing semiconductor integrated circuits having a twin-well type CMIS (Complimentary MIS) circuit, but the present invention can be also applied to other various types of semiconductor integrated circuits.

As shown in FIG. 6A, a substrate 3s constituting a semiconductor wafer is formed of, for example, disc-shaped n⁻-type Si single crystal. A wafer alignment mark (not shown) for mask alignment is formed on the substrate 3s. This wafer alignment mark may be also formed during the formation of wells by adding a selective oxidation step.

Subsequently, an oxide film 17 is formed on the substrate 3s, and then a resist pattern 18 for an ion-implantation masking is formed on the oxide film 17 using ordinary optical lithography. Thereafter, P (phosphorus) or As is ion-implanted, resulting in an n-type well 6n.

Next, the resist pattern 18 is removed by ashing process, and then the oxide film 17 is also removed, and then an oxide film 19 is formed on the substrate 3s as shown in FIG. 6B. Then, a resist pattern 20 for ion-implantation masking is formed on the oxide film 19 using ordinary optical lithography. Thereafter, B (boron) is ion-implanted, resulting in a p-type well 6p.

Next, the resist pattern 20 is removed by ashing process, and then the oxide film 19a is also removed, and then, as shown in FIG. 6C, a field insulating film 7 for isolation is formed of, e.g., silicon oxide in a grooved isolation configuration on the substrate 3s. For the method of isolation, LOCOS (Local Oxidization of Silicon) may be used.

The isolation configuration has a minimum dimension as small as 36 nm on the wafer, its dimensional accuracy requirement being as strict as 3.5 nm. Therefore, EUV lithography can be employed for the lithography for fabrication of this isolation.

At this time, the resist surface modifying process described above can be applied thereto.

In an active region surrounded by the field insulating film 7, an n-MIS transistor Qn and a p-MIS transistor Qp are formed. A gate insulating film 8 of each transistor is made of, for example, silicon oxide using thermal oxidation process or the like. Also, a gate electrode 9 of each transistor has a minimum dimension, for example, as small as 32 nm on the wafer, its dimensional accuracy requirement being as strict as 3 nm. Accordingly, a gate-forming film of low-resistivity polysilicon is deposited using, e.g., CVD process, and then a resist pattern is formed using EUV lithography, and then the gate electrode 9 is formed using etching process. At this time, the resist surface modifying process described above can be applied thereto.

A semiconductor region 10 of the n-MIS transistor Qn is formed in a self-aligned manner with respect to the gate electrode 9 by introducing, for example, P (phosphorus) or As into the substrate 3s with the gate electrode 9 used as a mask using ion implantation process or the like. Also, a semiconductor region 11 of the p-MIS transistor Qp is formed in a self-aligned manner with respect to the gate electrode 9 by introducing, for example, B (boron) into the substrate 3s with the gate electrode 9 used as a mask using ion implantation process or the like.

The gate electrode 9 is not necessarily a single film made of low-resistivity polysilicon, and may also have, for example, a so-called polycide structure where a silicide film made of tungsten silicide, cobalt silicide, etc, is formed on the low-resistivity polysilicon. Alternatively, the gate electrode 9 may also be provided in a so-called polymetal structure in which a barrier conductor film of titanium nitride, tungsten nitride, etc, is interposed on the low-resistivity polysilicon and thereover a metal film of tungsten or the like is formed.

Next, as shown in FIG. 6D, an interlayer insulating film 12 of silicon oxide is deposited on the substrate 3s using, e.g., CVD process, and then a polysilicon film for interconnection is deposited on top of the interlayer insulating film 12 using CVD process or the like. Subsequently, lithography is carried out on the polysilicon film, and then patterned by etching, and thereafter impurities are introduced to specified regions of the patterned polysilicon film, resulting in interconnections 13L and 13R.

Next, as shown in FIG. 6E, a silicon oxide film 14 is deposited on the substrate 3s using, e.g., CVD process. Then, a resist pattern is formed using EUV lithography for the interlayer insulating film 12 and the silicon oxide film 14, and then contact holes 15 are formed using etching process to partially expose the semiconductor regions 10 and 11 and the interconnection 13L.

An opening diameter of the contact hole 15 is very small, e.g., 45 nm, to which EUV lithography is therefore applied. In this case, a conventional resist treatment is performed without employing the resist surface modifying process described above. This is because a pattern of the contact holes 15 is not so dense, hence, the pattern collapsing is unlikely to occur. However, in another case where the opening diameter of the contact hole 15 is as extremely small as about 28 nm, micro-swelling may cause a failure of opening. In that case, the resist surface modifying process as described above may be performed so that a production yield can be improved.

Next, as shown in FIG. 6F, metal films made of Ti (titanium), TiN and W (tungsten) are sequentially deposited on the substrate 3s using, e.g., sputtering process or CVD process, and thereafter a resist is formed on these metal films using EUV lithography and then etched so that a first interconnect layer 16L1 is formed. Since a pitch of the interconnection is very small, e.g., 64 nm, EUV lithography is employed. In this case, application of the resist surface modifying process described above allows to prevent the resist pattern from collapsing even if it has a very dense and fine dimension, thereby improving a interconnection yield.

Subsequently, alike as the first interconnect layer 16L1, a second interconnect layer (not shown) can be also formed, thereby manufacturing a final product.

In the above description, an example is given of a case where the present invention is applied to the CMIS circuit, however, the present invention is not limited thereto and can also be applied to other various semiconductor devices such as a semiconductor integrated circuit including a memory circuit, for example, SRAM (Static Random Access Memory) or a flash memory (EEPROM: Electric Erasable Read Only Memory), a mixed type of semiconductor integrated circuit including the memory circuit and a logic circuit on the same substrate, a wiring substrate device, and a magnetic recording device. The effect of the present invention can be particularly exerted in the semiconductor integrated circuit including the memory circuit in which collapsing of the resist pattern is more likely to occur because a large number of line-shaped fine and dense patterns are used therein.

When the resist surface modifying process according to the present invention is thus applied to the steps for providing the isolation, gate and interconnection, even a very fine pattern can be prevented from collapsing as seen before, thereby reliably retaining higher uniformity of development and uniformity of dimension within the substrate. As a result, a production yield in a semiconductor device, such as a semiconductor integrated circuit, can be improved.

Further, among all the lithography steps, the present invention is preferably selectively applied only to steps in which the pattern collapse preventing effect can be more efficiently achieved, which can control deterioration of throughput of the lithography steps to minimum. As a result, any increase in manufacturing costs can be minimized.

### Embodiment 3

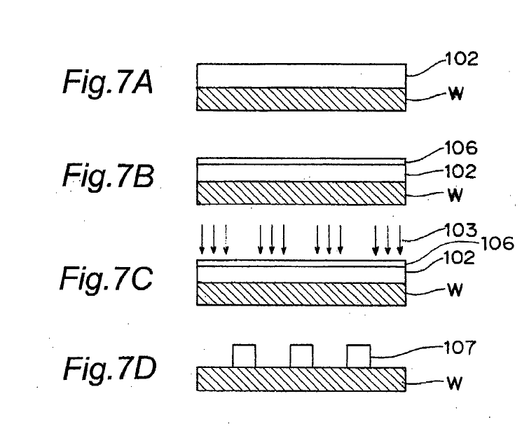

FIGS. 7A to 7D are sectional views showing another example of a resist treatment process. First, as shown in FIG. 7A, a resist is applied onto a wafer W, and then thermally treated in a conventional manner so that a resist film 102 is formed. In the case of optical lithography, an anti-reflective film, such as BARC (Bottom Anti-Reflective Coating), is formed prior to application of the resist. On the other hand, the anti-reflective film is not necessary in the case of EUV lithography.

Herein, similar to Embodiment 1, a developer-repellent resist material is used for the resist. For example, a resist material having a contact angle with a developer of at least 65 degrees is preferably used. In this embodiment, an alkali aqueous solution is used as the developer.

Next, as shown in FIG. 7B, an overcoat process is performed for forming a thin film 106 having solubility in an alkali aqueous solution on a surface of the resist film 102. A thickness of the thin film 106 is, for example, about 10 nm, however, may be thinner than 10 nm, e.g., about 5 nm, as long as it has a sufficient level of developer wettability on the surface. However, the thin film 106 having too large thickness may invite absorption of exposure light therein, therefore the thickness thereof is preferably about 10 nm.

The thin film 106 is formed of, e.g., a water-soluble fluoroalcohol film, which has a contact angle of 10 degrees or below with the developer. The contact angle with the developer is preferably as small as possible, but favorable results can be stably obtained as long as the contact angle is 20 degrees or below.

The process as shown in FIGS. 7A and 7B are carried out inside the resist treatment equipment 121 as shown in FIG. 3. Thereafter, the wafer W is transported via the transport mechanism 124 and the load lock loader unit 122b into the exposure unit 122a.

Next, an exposure process is performed to the resist film 102. As shown in FIG. 7C, the resist film 102 is irradiated with exposure light 103, which is projected by a projection optical system with a mask pattern having a desired pattern. In the case of using EUV light having a wavelength of 13.5 nm for the exposure light 103, the exposure is performed in vacuum. After the exposure, the wafer W is transported to the resist treatment equipment 121 as shown in FIG. 3.

Next, the exposed resist film 102 is developed using the alkali aqueous solution as the developer to obtain a resist pattern 107 as shown in FIG. 7D. The resist film 102 is made of the developer-repellent resist material, which makes it difficult for the developer to penetrate into a side wall of the resist. On the other hand, an upper surface of the resist film 102, where the contact angle with the developer is reduced due to presence of the thin film 106, now obtains such a property that is more familiar with the developer. Therefore, higher uniformity of development and uniformity of dimension within the wafer surface are reliably retained, and micro-swelling on the resist side wall can be prevented as well. As a result, the resist pattern can be reliably prevented from collapsing as shown in FIG. 2.

As described above, the present embodiment can successfully prevent a pattern from collapsing as seen before even if it has a very fine dimension, thereby reliably retaining higher uniformity of development and uniformity of dimension within the wafer surface. As a result, a production yield in a semiconductor device, such as a semiconductor integrated circuit, can be improved.

In particular, according to the present embodiment, the overcoat process of the thin film 106 can be carried out in the atmosphere, therefore, it can be easily added to the conventional lithography device.

In the above description, a semiconductor wafer as a substrate to the processed is exemplified, however, the present invention can be applied to various semiconductors, metals and dielectric materials such as glass substrates.

### INDUSTRIAL APPLICABILITY

The present invention, which is capable of manufacturing a semiconductor device including a very fine and highly accurate pattern with a high efficiency of production, is industrially very advantageous.

1-12. (canceled)

13. A method of manufacturing a semiconductor device comprising steps of:
forming a resist film made of a developer-repellent material on a substrate or a film to be processed;
exposing the resist film with a desired pattern of light;
oxidizing a surface layer of the resist film to hydrophilize the surface layer; and
developing the resist film using a developer after the oxidizing step, to form a resist pattern;
wherein the oxidizing step is performed at a reduced pressure.

14. A method of manufacturing a semiconductor device comprising steps of:
forming a resist film made of a developer-repellent material on a substrate or a film to be processed;
exposing the resist film with a desired pattern of light;
oxidizing a surface layer of the resist film to hydrophilize the surface layer; and
developing the resist film using a developer after the oxidizing step, to form a resist pattern;
wherein the oxidizing step is performed at a reduced pressure with an oxygen partial pressure of at least 20%.

15. A method of manufacturing a semiconductor device comprising steps of:
forming a resist film made of a developer-repellent material on a substrate or a film to be processed;
exposing the resist film with a desired pattern of light;
oxidizing a surface layer of the resist film to hydrophilize the surface layer; and
developing the resist film using a developer after the oxidizing step, to form a resist pattern;
wherein the exposing step is performed using EUV light for the exposure light.

16. A method of manufacturing a semiconductor device comprising steps of:
forming a resist film made of a developer-repellent material on a substrate or a film to be processed;
exposing the resist film with a desired pattern of light;
oxidizing a surface layer of the resist film to hydrophilize the surface layer; and
developing the resist film using a developer after the oxidizing step, to form a resist pattern;
wherein the exposing step and the oxidizing step are performed without undergoing the atmosphere between the both steps.

17. A method of manufacturing a semiconductor device comprising steps of:
forming a resist film made of a developer-repellent material on a substrate or a film to be processed;
exposing the resist film with a desired pattern of light;
oxidizing a surface layer of the resist film to hydrophilize the surface layer; and
developing the resist film using a developer after the oxidizing step, to form a resist pattern;
wherein a contact angle of the surface layer of the resist film with the developer is at least 65 degrees.

18. A method of manufacturing a semiconductor device comprising steps of:
forming a resist film made of a developer-repellent material on a substrate or a film to be processed;
forming a thin film having solubility in an alkali aqueous solution on the resist film;
exposing the resist film with a desired pattern of light;
developing the resist film using an alkali aqueous solution as a developer to form a resist pattern.

19. An apparatus for manufacturing a semiconductor device comprising:
an exposure unit for exposing a specimen with a desired pattern of light in vacuum, the specimen being provided with a resist film on a substrate or a film to be processed;
a resist modifying unit for modifying a surface layer of the resist film at a reduced pressure, and
a transport mechanism for transporting the specimen between the exposure unit and the resist modifying unit without undergoing the atmosphere.
